(19) United States
(12) Patent Application Publication
(10) Pub. No.: US 2010/0329013 A1
(43) Pub. Date: Dec. 30, 2010

(54) SEMICONDUCTOR MEMORY DEVICE INCLUDING NONVOLATILE MEMORY CELL AND DATA WRITING METHOD THEREOF

(76) Inventors: Go SHIKATA, Kawasaki-shi (JP); Yuya Suzuki, Yokohama-shi (JP)

Correspondence Address: OBLON, SPIVAK, MCCLELLAND MAIER & NEUSTADT, L.L.P., 1940 DUKE STREET, ALEXANDRIA, VA, 22314, US

(21) Appl. No.: 12/759,941

(22) Filed: Apr. 14, 2010

(30) Foreign Application Priority Data
Jun. 25, 2009 (JP) 2009-151247

(51) Int. Cl. G11C 16/04

(52) U.S. Cl. 365/185.18

(57) ABSTRACT

A semiconductor memory device includes memory cells, bit lines, and first and second control circuits. The first control circuit supplies a write voltage and a write control voltage to a selected memory cell to write the data in the selected memory cell, the first control circuit changes a supply state of the write control voltage to further write the data when the selected memory cell reaches a first write state by the write, the first control circuit further changes the supply state of the write control voltage to prohibit the write when the selected memory cell reaches a second write state by the write. The second control circuit controls a rising of the write control voltage when the first control circuit starts the writing to make the selected memory cell the second write state.

### CROSS-REFERENCE TO RELATED APPLICATIONS

This application is based upon and claims the benefit of priority from prior Japanese Patent Application No. 2009-151247, filed Jun. 25, 2009, the entire contents of which are incorporated herein by reference.

### BACKGROUND OF THE INVENTION

1. Field of the Invention

The present invention relates to a semiconductor memory device including a nonvolatile memory cell and a data write method thereof, particularly to a NAND cell EEPROM (NAND flash memory) that can perform a Quick Pass Write (hereinafter referred to as QPW) operation during a program (write) operation.

2. Description of the Related Art

A nonvolatile memory cell transistor in which a charge accumulation layer (floating gate) and a control gate are stacked is used as a storage element in the electrically-rewritable NAND flash memory. For example, data is written in the memory cell transistor by injecting electrons into the floating gate. A cell current that changes according to injection/non-injection of the electrons in the floating gate is sensed with a sense amplifier, thereby performing data read (read operation).

Recently, a multi-level flash memory in which a storage capacity per one memory chip can be increased while the unit price per bit is reduced is receiving attention in the field of NAND flash memories. In the multi-level flash memory, data of plural bits having different threshold voltages is stored in one memory cell transistor. For example, for the memory cell transistor in which two-bit data is stored, each memory cell transistor has four threshold levels (threshold voltage distribution) according to the data. The number of threshold levels increases in proportion with the number of bits stored in one memory cell transistor.

On the other hand, in the NAND flash memory, there is a tendency to lower the internal power supply voltage. That is, in order to obtain a high-reliability device, it is necessary to accurately control the threshold voltage of the memory cell transistor.

As to a technique for accurately controlling the threshold voltage of a memory cell transistor, there is proposed a method in which the write voltage (program voltage Vpgm) is divided into plural write pulses and the data write is repeated while the voltage of each pulse is stepped up with a constant rate (ΔVpgm). The threshold voltage of the memory cell transistor that changes every time the write pulse is applied is verified, and the application of the write pulse is stopped to end the data write when the threshold voltage reaches a predetermined verify level. For example, when a step-up voltage (ΔVpgm) of the write pulse is set to 0.2V, a distribution width of one threshold voltage can be controlled up to 0.2V, in principle. When the step-up voltage is made finer, the distribution width of the threshold voltage can be narrowed. However, a large number of write pulses are required for the data write, which results in a problem in that a write time is lengthened.

Additionally, a distance between memory cell transistors is shortened with the progress of microfabrication of processing dimensions, which prominently results in a problem in that the threshold voltage of the memory cell transistor varies due to capacitance coupling between adjacent floating gates. At this point, a threshold voltage difference (read margin) decreases in each memory cell transistor.

For example, Jpn. Pat. Appln. KOKAI Publication No. 2003-196988 discloses a QPW operation as a method for avoiding such problems. In the QPW operation, the distribution width of the threshold voltage can be narrowed after the data write while also preventing an increase in the write time (the number of write pulses).

However, in the conventional QPW operation, when a potential level at a bit line is clamped to voltage VQPW, unfortunately, a large peak current is passed through the bit line. For example, in the QPW operation, the potential level at the bit line connected to a write cell (selected memory cell transistor) is clamped to voltage VSS (0V) before the write pulse is applied. The potential level at the bit line connected to a non-write cell (non-selected memory cell transistor) is clamped to voltage VDDSA (for example, 2.2V) before the write pulse is applied. The potential level at the bit line connected to the write cell in which the threshold voltage passes a verify low level (verify low level<verify level) is clamped to voltage VQPW (for example, 0.6V) before the write pulse is applied. That is, in the QPW operation, it is necessary that the potential level at each bit line be controlled by the sense amplifier provided in each bit line according to the threshold voltage of the memory cell transistor that becomes the target/non-target of the data write. Therefore, each sense amplifier is configured to be able to generate three kinds of bit line voltages (VSS<VQPW<VDDSA). However, as the number of blocks increases with increased capacity, the bit line length and page length also increase. Therefore, when the write cell that passes the verify low level increases, unfortunately, a large peak current is passed in charging the bit line.

Thus, in the NAND flash memory that can perform the QPW operation, particularly, for a sense amplifier in which a signal VQPW+Vtn (Vtn is a threshold voltage of an SET transistor) is applied to a gate of the SET transistor to supply a voltage from a BUS line to the bit line in order to charge the bit line connected to the write cell whose threshold voltage passes the verify low level, when the potential level at the bit line is clamped to the voltage VQPW, it is necessary to quickly turn on the SET transistor (for example, with an interconnection delay of only 20 ns) because of the necessity to sufficiently charge the long bit line, and there are many bit lines in the data write, which results in the problem in that a large peak current is passed through the bit line.

### BRIEF SUMMARY OF THE INVENTION

A semiconductor memory device according to an aspect of the present invention includes:

a plurality of nonvolatile memory cells in which pieces of data are stored as thresholds having different levels;

a plurality of bit lines which are connected to the nonvolatile memory cells;

a first control circuit which supplies a write voltage and a write control voltage to a selected memory cell to write the data in the selected memory cell, the first control circuit changing a supply state of the write control voltage to further write the data when the selected memory cell reaches a first write state by the write, the first control circuit further changing the supply state of the write control voltage to prohibit the write when the selected memory cell reaches a second write state by the write; and

a second control circuit which controls a rising of the write control voltage when the first control circuit starts the writing to make the selected memory cell the second write state.

A method for writing data of a semiconductor memory device according to an aspect of the present invention includes:

supplying a write voltage and a write control voltage to a memory cell to perform first write of data to the memory cell;

changing a supply state of the write control voltage to perform second write when the memory cell reaches a first write state by the first write; and

changing further the supply state of the write control voltage to prohibit the write when the memory cell reaches a second write state by the second write,

wherein a rising speed of the write control voltage is slowed.

### BRIEF DESCRIPTION OF THE SEVERAL VIEWS OF THE DRAWING

FIG. 1 is a block diagram illustrating a configuration example of a nonvolatile semiconductor memory device (multi-level NAND flash memory) according to a first embodiment of the present invention;

FIG. 2 is a plan view of the flash memory of FIG. 1;

FIG. 3 is a block diagram of a memory cell array of FIG. 1;

FIG. 4 is a circuit diagram of a block in the memory cell array of FIG. 3;

FIG. 5 is a sectional view taken along a column direction of the memory cell array of FIG. 3;

FIG. 6 illustrates a threshold voltage distribution of a memory cell transistor in the flash memory of FIG. 1;

FIG. 7 is a circuit diagram of a sense amplifier circuit of FIG. 1;

FIG. 8 and FIG. 9 are sectional views taken along a column direction of the memory cell array;

FIG. 10 is a waveform chart of a write pulse in the flash memory of FIG. 1;

FIG. 11 illustrates a data write/verify operation (verify write) of the flash memory of FIG. 1;

FIG. 12 illustrates a QPW operation (verify sense) of the flash memory of FIG. 1;

FIG. 13A illustrates a state in which a memory cell threshold is sequentially increased in the QPW operation (verify sense) of the flash memory of FIG. 1;

FIG. 13B illustrates a write state of the memory cell in a distribution in the QPW operation (verify sense) of the flash memory of FIG. 1;

FIG. 14 is a sectional view taken along a column direction of the memory cell array;

FIG. 15 illustrates a relationship between two-bit data and threshold voltage in the flash memory of FIG. 1;

FIG. 16 is a circuit diagram of a gate voltage control circuit;

FIG. 17 illustrates a set-on time of a SET transistor as contrasted with a conventional technique;

FIG. 18 illustrates a relationship between a peak current at a set-on time and power supply voltage drop in the SET transistor as contrasted with a conventional technique;

FIG. 19 is a timing chart illustrating the QPW operation of the first embodiment;

FIG. 20 is a plan view illustrating another configuration example (layout example of memory cell array) of the flash memory of the first embodiment;

FIG. 21 is a plan view illustrating a method for controlling a gate voltage of a SET transistor according to a second embodiment of the present invention;

FIG. 22 illustrates the method for controlling the gate voltage of the SET transistor of the second embodiment;

FIG. 23 is a circuit diagram illustrating a configuration example of a gate voltage control circuit that controls the gate voltage of the SET transistor of the second embodiment;

FIG. 24 is a timing chart illustrating a QPW operation during a program operation of the second embodiment;

FIG. 25 is a plan view illustrating another method for controlling the gate voltage of the SET transistor of the second embodiment;

FIG. 26 and FIG. 27 are plan views illustrating a method for controlling a gate voltage of a SET transistor according to a third embodiment of the present invention; and

FIG. 28 is a timing chart illustrating a QPW operation according to another embodiment of the present invention.

### DETAILED DESCRIPTION OF THE INVENTION

Embodiments of the present invention will be described in detail with reference to the drawings. However, note that as the drawing is schematic, dimensions and ratios shown in each drawing are different from actual dimensions and ratios. Naturally, the drawings differ from one another in dimensional relationship and/or ratio. Particularly, in the following embodiments, an apparatus and method for realizing the technical idea of the present invention are illustrated only by way of example, and the technical idea of the present invention is not specified by shapes, structures, and arrangements of components. Various changes and modifications can be made without departing from the scope of the technical idea of the present invention.

### First Embodiment

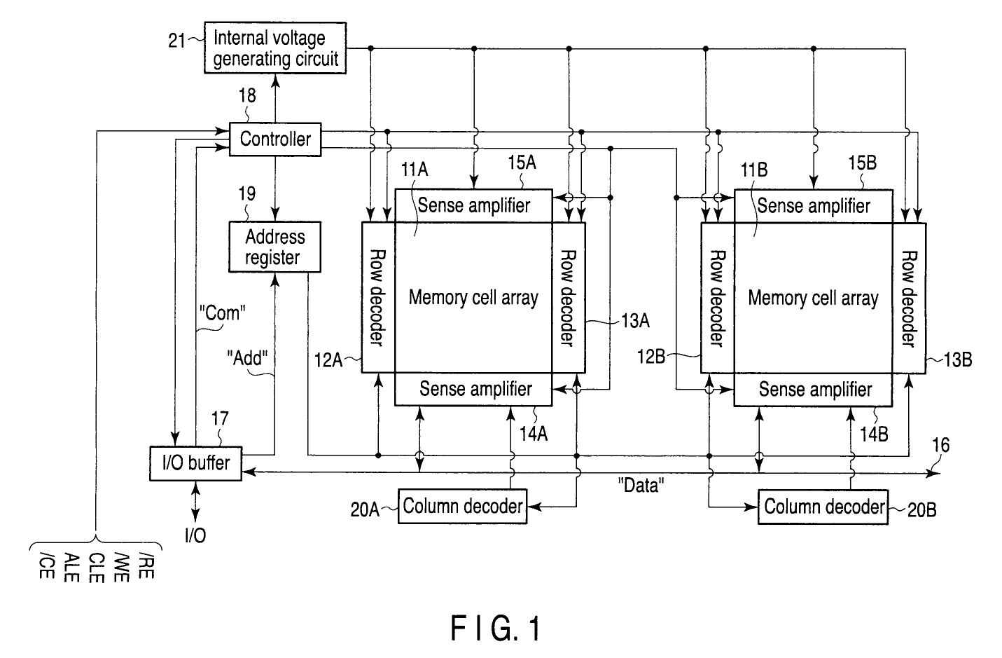

FIG. 1 illustrates a configuration example (functional block) of a nonvolatile semiconductor storage device according to a first embodiment of the present invention. The first embodiment is an example of a multi-level NAND flash memory with a two-plane memory cell array which supports the QPW operation.

Referring to FIG. 1, row decoders (Rowdec) 12A and 13A and 12B and 13B are disposed in end portions in a word line (WL) direction of two memory cell arrays 11A and 11B, respectively. Sense amplifiers (S/A) 14A and 15A and 14B and 15B are disposed in end portions in a bit line (BL) direction of two memory cell arrays 11A and 11B, respectively. Transmission and reception of data “Data” between the sense amplifiers 14A and 14B and an external input/output terminal I/O are performed through a data bus (BUS line) 16 and a data buffer (I/O buffer) 17.

Various external control signals (such as a chip enable signal /CE, an address latch enable signal ALE, a command latch enable signal CLE, a write enable signal /WE, and a read enable signal /RE) are fed into a controller 18. The controller 18 identifies an address “Add” and a command “Com” based on the control signals, and the address “Add” and the command “Com” are supplied to the data buffer 17 through the external input/output terminal I/O. The address “Add” is transferred to the row decoders 12A, 12B, 13A, and 13B and the column decoders 20A and 20B through an address register 19. The controller 18 decodes the command “Com”. Plural (in FIG. 1, two) cell arrays, or one cell array, is specified by the address “Add”, so that multi-plane controls in which the plural cell arrays are simultaneously controlled or one-plane (single-plane control) in which the plural cell arrays are individually controlled can be performed. The controller 18 performs sequence control according to operation modes such as data read, data write, and data erasing based on the external control signals and the command “Com”.

An internal voltage generating circuit 21 is provided in order to generate the internal voltage necessary for each operation mode. The controller 18 controls the internal voltage generating circuit 21, and the internal voltage generating circuit 21 performs a boosting operation for generating the necessary internal voltage from the power supply voltage (VDD).

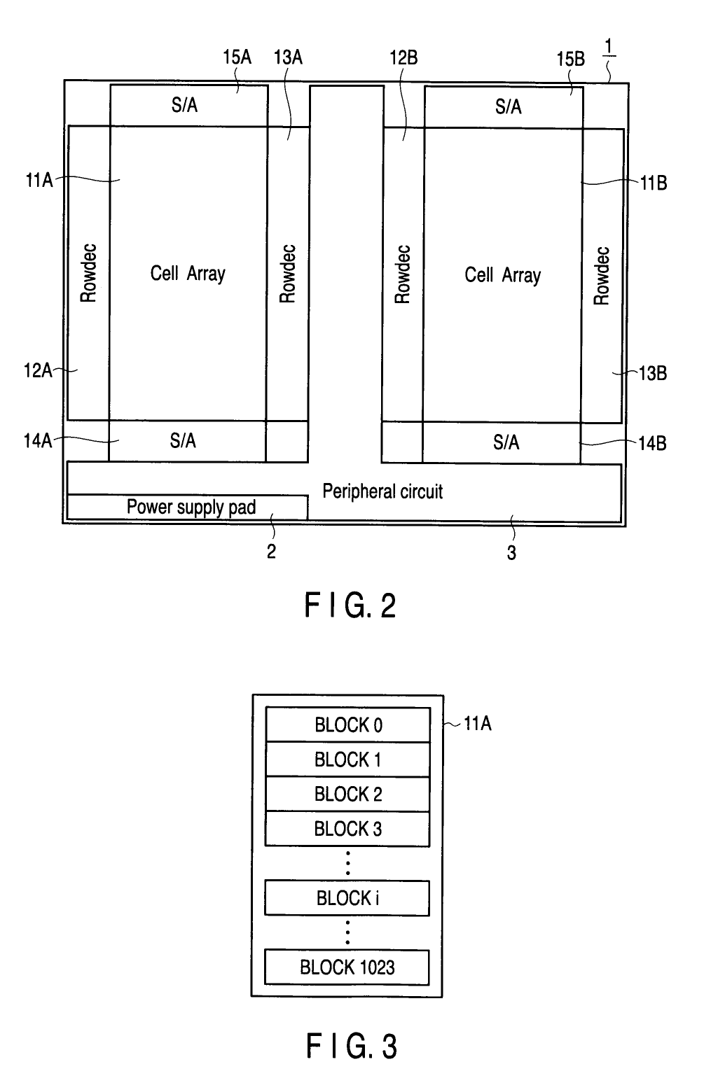

FIG. 2 illustrates a layout example in which the multi-level flash memory of FIG. 1 is formed on a chip. As illustrated in FIG. 2, a power supply pad 2 to which the power supply voltage is supplied from the outside is disposed on a chip 1. The two memory cell arrays 11A and 11B are disposed along the word line direction (row direction) on the chip 1.

The sense amplifier 14A is disposed at one end in the bit line direction (column direction) of the memory cell array 11A, and the sense amplifier 15A is disposed at the other end in the bit line direction of the memory cell array 11A. The row decoder 12A is disposed at one end in the word line direction of the memory cell array 11A, and the row decoder 13A is disposed at the other end in the word line direction of the memory cell array 11A.

Similarly, the sense amplifier 14B is disposed at one end in the bit line direction of the memory cell array 11B, and the sense amplifier 15B is disposed at the other end in the bit line direction. The row decoder 12B is disposed at one end in the word line direction of the memory cell array 11B, and the row decoder 13B is disposed at the other end in the word line direction.

Peripheral circuits 3 are disposed between the power supply pad 2 and the sense amplifiers 14A and 14B and between the row decoders 13A and 12B in order to drive the memory cell arrays 11A and 11B. For example, the data buffer 17, the controller 18, address register 19, the column decoders 20A and 20B, and the internal voltage generating circuit 21 are disposed as the peripheral circuit 3.

The data bus 16 and a power supply interconnection through which the power supply voltage is supplied from the power supply pad 2 to the sense amplifiers 15A and 15B are not illustrated in FIG. 2.

For example, when the memory cell array is divided into at least two planes in the word line direction, a large capacity can be achieved while also maintaining performance as a flash memory. That is, in order to satisfy the need for a large capacity, the page length is increased, and the number of blocks (the number of pages) is increased. Additionally, the bit line and the word line are lengthened and thinned with the progress of microfabrication. Therefore, the interconnection resistance increases in the bit line and the word line, thereby lengthening a charge time (charge speed). On the other hand, in the first embodiment, the memory cell array is divided to prevent the word line and the bit line from being lengthened, so that the degradation of the charge speed can be improved. The bit line length and the word line length can be shortened by preparing plural planes on the one chip, and therefore the degradation of the write speed and read speed can be prevented.

FIG. 3 illustrates a configuration example of the memory cell arrays 11A and 11B. Because the memory cell arrays 11A and 11B basically have the same configuration, only the memory cell array 11A is described by way of example.

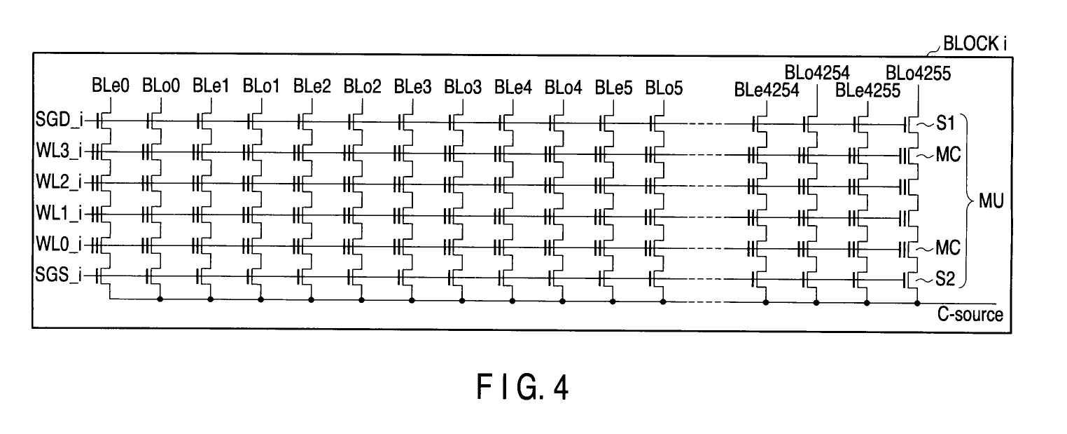

The memory cell array 11A is divided into plural blocks BLOCK (in the first embodiment, BLOCK0 to BLOCK1023). The block BLOCK is a minimum unit when erasing data. As illustrated in FIG. 4, plural (for example, 8512) NAND memory units MU are provided in each block BLOCKi (i is a natural number of 0 to 1023).

For example, four memory cell transistors MC are provided in each NAND memory unit MU. In each NAND memory unit MU, the memory cell transistor MC in one of end portions is connected to a corresponding bit line BL (BLe0 to BLe4255 or BLo0 to BLo4255) through a select gate S1 that is commonly connected to a select gate line SGD_i. The memory cell transistor MC in the other end portion is connected to a common source line c-source through a select gate S2 that is commonly connected to a select gate line SGS_i.

Each of the memory cell transistors MC includes a control gate, a floating gate (charge accumulation layer), a source, and a drain. In each NAND memory unit MU, the control gate of each of the four memory cell transistors MC is commonly connected to one of the corresponding word lines WL (WL0_{—}i to WL3_{—}i). In each NAND memory unit MU, each memory cell transistor MC is a NAND cell type flash memory cell (nonvolatile storage element), and the memory cell transistors MC are connected in series.

A data write operation and a data read operation are independently performed to even-numbered bit lines BLe and odd-numbered bit lines BLo. For example, in 8512 memory cell transistors MC whose control gates are commonly connected to one word line WL, the data write operation and the data read operation are simultaneously performed to the 4256 memory cell transistors MC that are connected to even-numbered bit lines BLe. When one-bit data is stored in each memory cell transistor MC, the pieces of data of 4256 bits stored in the 4256 memory cell transistors MC make one page unit. Therefore, when two-bit data is stored in one memory cell transistor MC, two pages of data are stored in the 4256 memory cell transistors MC. Accordingly, the 4256 memory cell transistors MC that are connected to the odd-numbered bit lines BLo makes another page, and the data write operation and the data read operation are simultaneously performed to the 4256 memory cell transistors MC making another page.

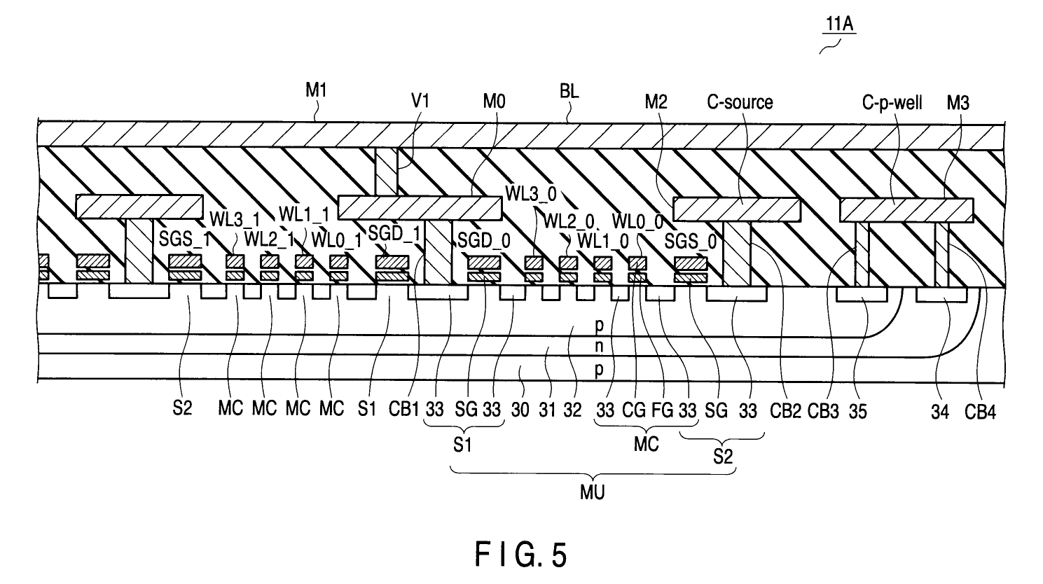

FIG. 5 illustrates a sectional structure in a column direction (direction along the bit line BL) of the memory cell arrays 11A and 11B. Because the memory cell arrays 11A and 11B basically have the same configuration, only the memory cell array 11A is described by way of example.

An n-type well 31 is formed on a p-type semiconductor substrate 30, and a p-type well 32 is formed in the n-type well 31. Each memory cell transistor MC includes the source and drain that are formed by a n-type diffusion layer 33, a floating gate FG that is provided on a channel region between the source and drain with a tunnel oxide film interposed therebetween, and a control gate CG that is provided on the floating gate FG with an insulating film interposed therebetween. The control gate CG functions as the word line WL.

Each select gate S1 is a MOS transistor which includes the source and drain formed by the n-type diffusion layer 33 and a gate electrode SG having a stacked structure. The gate electrode SG is connected to the select gate line SGD_i Each select gate S2 is a MOS transistor which includes the source and drain formed by the n-type diffusion layer 33 and the gate electrode SG having the stacked structure. The gate electrode SG is connected to the select gate line SGS_i. For example, the select gate lines SGD_i and SGS_i and the word line WL are connected to the row decoders 12A and 13A of FIG. 1 and controlled by signals supplied from the row decoders 12A and 13A.

The source/drain is shared by the adjacent memory cell transistors MC, and the source/drain is shared by one of the adjacent select gates S1 and S2 and the memory cell transistor MC located in the end portion. The source of the select gate S2 is shared by the adjacent memory units MU.

One end (for example, the drain of the select gate S1) of the NAND memory unit MU including the four memory cell transistors MC and the select gates S1 and S2 is connected to a metal interconnection layer M0 through a contact electrode (CB contact) CB1. The metal interconnection layer M0 is connected through a via hole electrode V1 to a metal interconnection layer M1 of a second layer functions as the bit line BL. For example, the bit line BL is connected to one of the sense amplifiers 14A and 15A of FIG. 1.

The other end (for example, the source of the select gate S2) of the NAND memory unit MU is connected through a contact electrode CB2 to a metal interconnection layer M2 of a first layer functioning as a common source line C-source. The common source line C-source is connected to a source line control circuit (not illustrated).

An n-type diffusion layer 34 is formed in a surface of the n-type well 31, and a p-type diffusion layer 35 is formed in a surface of the p-type well 32. Both the n-type diffusion layer 34 and the p-type diffusion layer 35 are connected through contact electrodes CB3 and CB4 to a metal interconnection layer M3 of the first layer functioning as a well line C-p-well. The well line C-p-well is connected to a p-type well control circuit (not illustrated).

In the configuration (FIGS. 4 and 5) of the first embodiment, the memory cell array with the bit line shielding type is illustrated. Alternatively, for example, the memory cell array may adopt an all bit line read (ABL) type. The number of memory cell transistors MC is not limited to four in the NAND memory unit MU.

Even in the configuration in which a two-plane memory cell array is formed in order to prevent the decreases in write speed and read speed caused by the increased bit line length and increased word line length, from the viewpoint of the requirements for large capacity and speed enhancement, the page length, which is the unit of reading and writing, becomes 4 Kbyte or more in the NAND flash memory. In such cases, because the pieces of data of 4 Kbyte or more corresponding to the page length unit are written simultaneously during the program operation, the peak current needed to charge the bit line inevitably increases.

A bit line shielding type sense amplifier and an all bit line reading type sense amplifier are well known in the NAND flash memory. In both the sense amplifiers, with the increasing page length in which the data write is simultaneously performed, the peak current required to charge the bit line increases. From the viewpoint of consumption current and the request on the system side, it is necessary to suppress the peak current to 100 mA or less. The peak current increases when the bit line charging speed is left unchanged while the page length is doubled or quadrupled, and the system malfunctions when the peak current exceeds 100 mA. That is, during the program operation, it is necessary to suppress the peak current in charging the bit line.

The QPW operation during the program operation in the multi-level flash memory will briefly be described below.

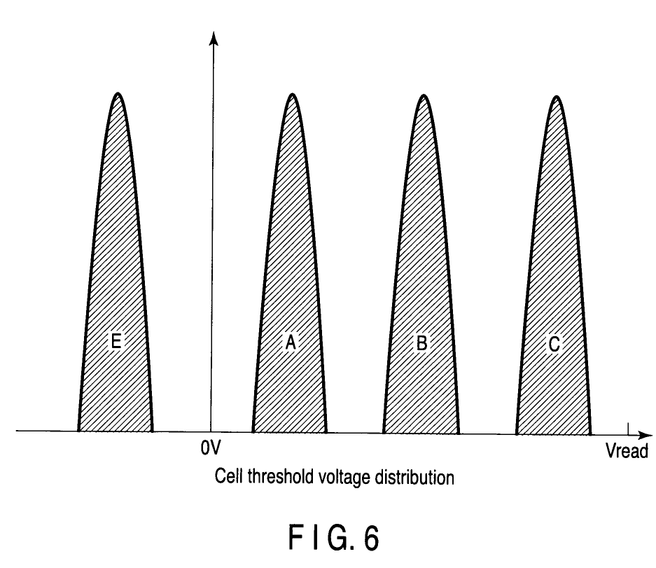

For example, as illustrated in FIG. 6, when two-bit data is stored in one memory cell transistor MC in the multi-level flash memory, the memory cell transistor MC has four threshold levels (threshold voltage distributions E, A, B, and C). The number of threshold levels increases in proportion with the number of bits stored in the memory cell transistor MC. On the other hand, there is a tendency to lower the internal power supply voltage of the multi-level flash memory. That is, in order to obtain a high-reliability device, it is necessary to accurately control the threshold voltage of the memory cell transistor.

For example, as to the technique for accurately controlling the threshold voltage of the memory cell transistor, there is the step-up writing method, in which the write voltage is divided into plural write pulses and the data write is repeated while the voltage of each pulse is stepped up at a constant rate. However, for the QPW operation in which the threshold distribution width can be narrowed without increasing the number of pulses, it is necessary that three kinds of bit line levels be simultaneously controlled with the sense amplifiers.

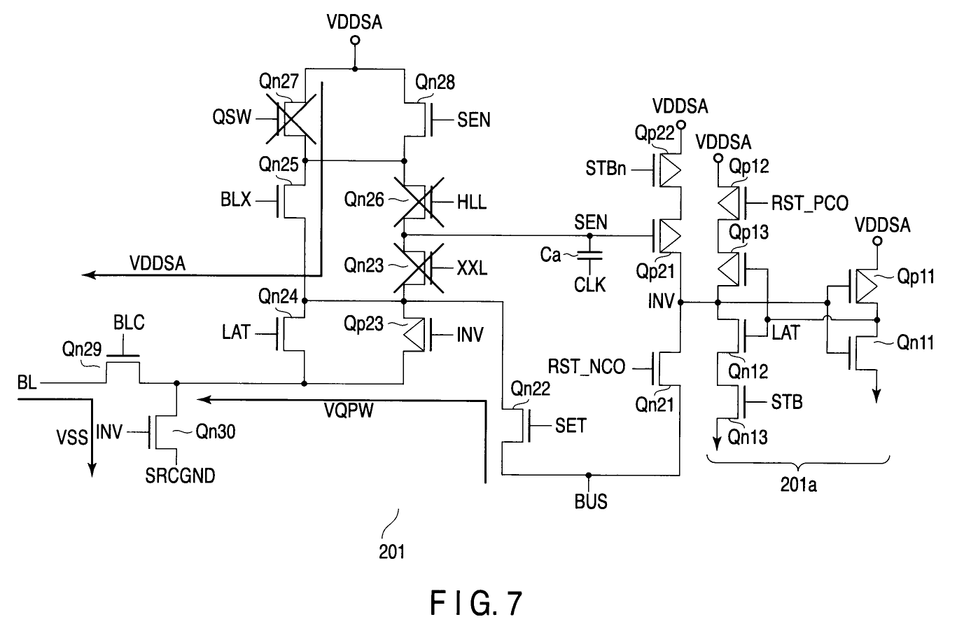

FIG. 7 illustrates a configuration example of the sense amplifiers 14A, 14B, 15A, and 15B that can perform the QPW operation. Because the sense amplifiers 14A, 14B, 15A, and 15B basically have the same configuration, only the sense amplifier 14A is described by way of example.

The sense amplifier 14A applies a voltage to the corresponding bit line BL according to the operation, and the sense amplifier 14A includes plural sense amplifier circuits 201. During the QPW operation, each of the sense amplifier circuits 201 has a function of biasing a potential level at the corresponding bit line BL to one of the three kinds of necessary voltages (for example, VDDSA, VSS, and VQPW (or occasionally referred to as Vb1)). The voltages VDDSA, VSS, and VQPW have a relationship of “VSS<VQPW<VDDSA”.

The sense amplifier circuit 201 includes an internal latch circuit 201a that retains the write data or the read data. The internal latch circuit 201a includes p-channel MOS transistors Qp11, QP12, and QP13 and n-channel MOS transistors Qn11, Qn12, and Qn13. One end of the current pass of the p-channel MOS transistor QP11 is connected to the power supply voltage VDDSA of the sense amplifier 14A, and the other end of the current pass of the p-channel MOS transistor QP11 is connected to one end of the current pass of the n-channel MOS transistor Qn11. The other end of the current pass of the n-channel MOS transistor Qn11 is grounded (voltage VSS). One end of the current pass of the p-channel MOS transistor Qp12 is connected to the power supply voltage VDDSA, and the other end of the current pass of the p-channel MOS transistor Qp12 is connected to one end of the current pass of the p-channel MOS transistor Qp13. The other end of the current pass of the p-channel MOS transistor Qp13 is connected to one end of the current pass of the n-channel MOS transistor Qn12. The other end of the current pass of the n-channel MOS transistor Qn12 is connected to one end of the current pass of the n-channel MOS transistor Qn13. The other end of the current pass of the n-channel MOS transistor Qn13 is grounded.

Gates of the p-channel MOS transistor Qp11 and the n-channel MOS transistor Qn11 are commonly connected to a connection point of the other end of the current pass of the p-channel MOS transistor Qp13 and one end of the current pass of the n-channel MOS transistor Qn12, and a signal INV is provided to the gates. Gates of the p-channel MOS transistor Qp13 and the n-channel MOS transistor Qn12 are commonly connected to a connection point of the other end of the current pass of the p-channel MOS transistor Qp11 and one end of the current pass of the n-channel MOS transistor Qn11, and a signal LAT that is a reversed phase of the signal INV is provided to the gates. A signal RST_PCO is provided to a gate of the p-channel MOS transistor Qp12, and a signal STB is provided to a gate of the n-channel MOS transistor Qn13.

Gates of the p-channel MOS transistor Qp11 and the n-channel MOS transistor Qn11 are commonly connected to a connection point of one end of the current pass of a p-channel MOS transistor Qp21 and one end of the current pass of an n-channel MOS transistor Qn21. The other end of the current pass of the p-channel MOS transistor Qp21 is connected to the power supply voltage VDDSA of the sense amplifier 14A through a p-channel MOS transistor Qp22. The other end of the current pass of the n-channel MOS transistor Qn21 is connected to one end of the current pass of an n-channel MOS transistor (SET transistor) Qn22 while also connected to the data bus (BUS line) 16. Therefore, during the QPW operation, a voltage is provided as a signal BUS to the other end of the current pass of the n-channel MOS transistor Qn21 and one end of the current pass of the n-channel MOS transistor Qn22 according to a result of write verify. A signal RST_NCO is provided to the gate of the n-channel MOS transistor Qn21, and a signal STBn is provided to the gate of the p-channel MOS transistor Qp22. One of electrodes of a capacitor Ca is connected to the gate of the p-channel MOS transistor Qp21, and a potential (signal SEN) at a node SEN is provided to the gate of the p-channel MOS transistor Qp21. A clock signal CLK is provided to the other electrode of the capacitor Ca. A signal SET is provided to the gate of the n-channel MOS transistor Qn22.

The other end of the current pass of the n-channel MOS transistor Qn22 is connected to a connection point of one end of the current pass of an n-channel MOS transistor Qn23 and one end of the current pass of a p-channel MOS transistor Qp23 and a connection point of one end of the current pass of an n-channel MOS transistor Qn24 and one end of the current pass of an n-channel MOS transistor Qn25. The other end of the current pass of the n-channel MOS transistor Qn23 is connected to the gate of the p-channel MOS transistor Qp21 and one end of the current pass of an n-channel MOS transistor Qn26. The other end of the current pass of the n-channel MOS transistor Qn26 is connected to a connection point of the other end of the current pass of the n-channel MOS transistor Qn25 and one end of the current pass of an n-channel MOS transistor Qn27 and one end of the current pass of an n-channel MOS transistor Qn28. The power supply voltage VDDSA is commonly connected to the other end of the current pass of the n-channel MOS transistor Qn27 and the other end of the current pass of the n-channel MOS transistor Qn28.

A signal XXL is provided to the gate of the n-channel MOS transistor Qn23, a signal INV is provided to the gate of the p-channel MOS transistor Qp23, a signal LAT is provided to the gate of the n-channel MOS transistor Qn24, a signal BLX is provided to the gate of the n-channel MOS transistor Qn25, a signal HLL is provided to the gate of the n-channel MOS transistor Qn26, a signal QSW is provided to the gate of the n-channel MOS transistor Qn27, and the signal SEN is provided to the gate of the n-channel MOS transistor Qn28.

One end of the current pass of an n-channel MOS transistor Qn29 and one end of the current pass of an n-channel MOS transistor Qn30 are connected to a common connection point of the other end of the current pass of the p-channel MOS transistor Qp23 and the other end of the current pass of the n-channel MOS transistor Qn24. The bit line BL is connected to the other end of the current pass of the n-channel MOS transistor Qn29, and a signal BLC is provided to the gate of the n-channel MOS transistor Qn29. The other end of the current pass of the n-channel MOS transistor Qn30 is connected to the common source line C-source (source line voltage SRCGND), and the signal INV is provided to the gate of the n-channel MOS transistor Qn30.

The signals are supplied from the corresponding column decoder 20A or the controller 18.

In the sense amplifier circuit 201 having the configuration of FIG. 7, the gate voltage (signal SET) at the n-channel MOS transistor Qn22 is gradually boosted with a gradient during the QPW operation. Therefore, the peak current passed through the bit line BL and a drop of the power supply voltage VDDSA can be prevented when the n-channel MOS transistor Qn22 is turned on.

The QPW operation in which the sense amplifier circuit 201 is used during the program operation will be described below.

The QPW operation that is already used in a multi-level flash memory will briefly be described before the first embodiment. When the QPW operation is performed during the program operation, the threshold voltage distribution width can be narrowed after the data write while also preventing an increase in the write time.

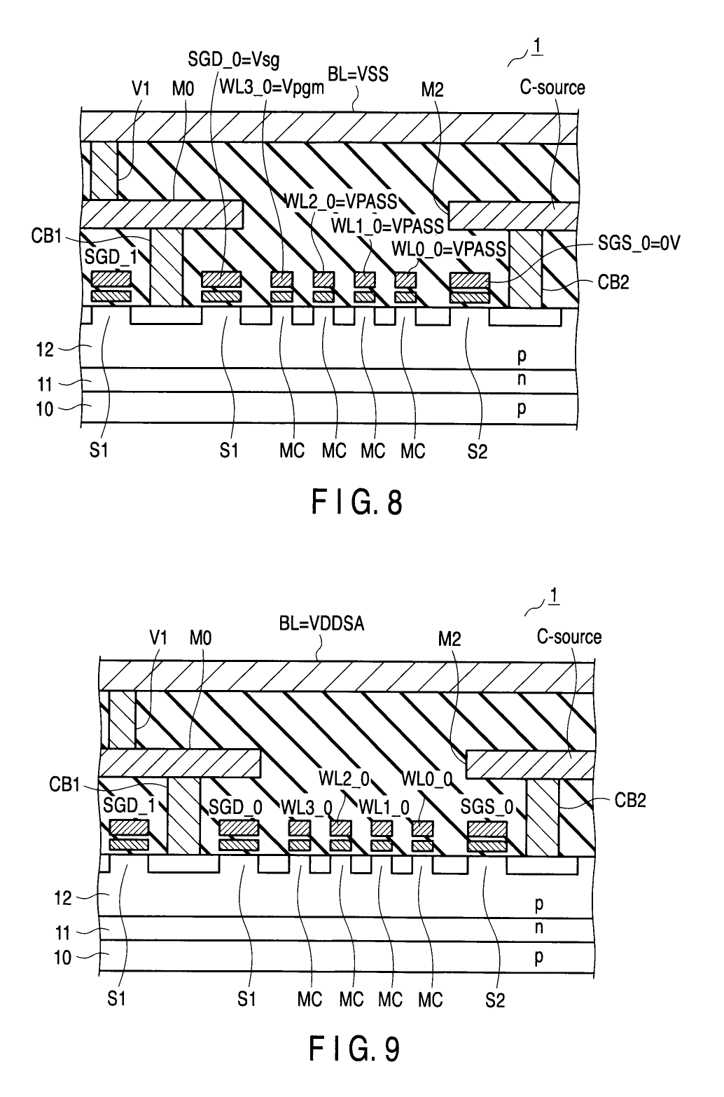

As described above, the data write is performed in units of pages during the program operation of the multi-level flash memory. For example, as illustrated in FIG. 8, the row decoder corresponding to the word line WL3_0 of the selected memory cell (write cell) MC applies a high voltage (write voltage Vpgm) (potentials at other word lines WL0_0, WL1_0, and WL20 is set to VPASS). For the selected memory cell MC to which the write should be performed, the sense amplifier circuit 201 biases the potential level at the corresponding bit line BL (also referred to as write BL or 0-BL) to the voltage VSS, and the row decoder turns on (SGD_0=Vsg and SGS_0=0V) the select gate S1 to set the channel region to the voltage VSS (0V). Therefore, in the selected memory cell MC, a high electric field is applied between the floating gate FG and channel region, and electrons are injected from the channel region side in the floating gate FG to write “0” data in the selected memory cell MC.

For example, as illustrated in FIG. 9, for the non-write memory cell (non-selected memory cell) MC, the potential level at the corresponding bit line BL (non-write BL or 1-BL) is biased to the voltage VDDSA, and the select gates S1 and S2 are cut off (SGD_0=Vsg and SGS_0=0V), thereby putting the channel region into a floating (Vinhibit) state. Therefore, a high electric field is not applied between the floating gate FG and the channel region, and “0” data is not written in the non-selected memory cell MC.

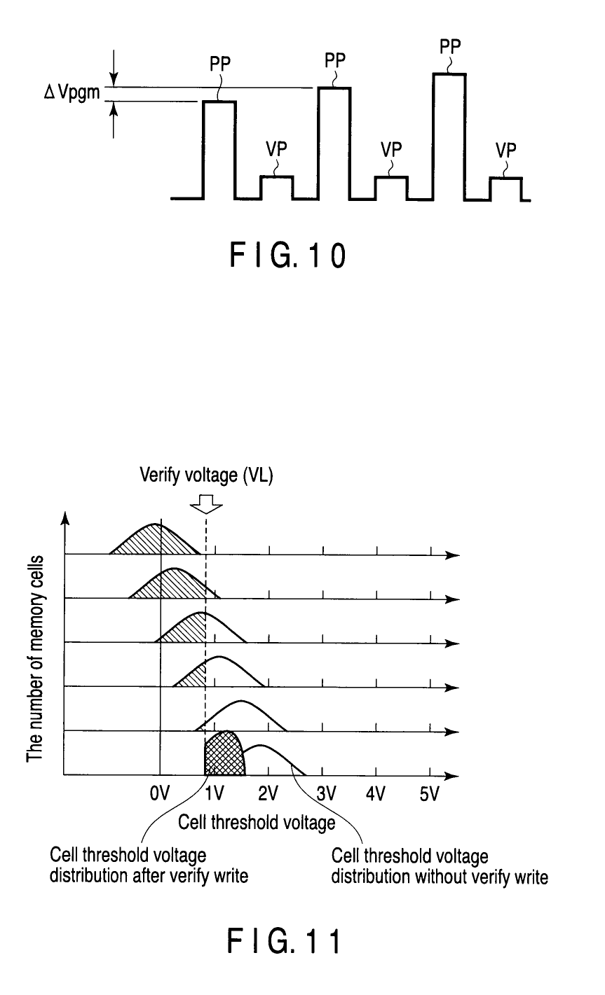

For example, as illustrated in FIG. 10, normally the program operation in the NAND flash memory is performed by a repetitive operation in which the corresponding row decoder applies a verify pulse VP to the selected word line WL to perform the verify after applying a write pulse PP to the selected word line WL to write the data in the selected memory cell MC. In the verify operation after the write, when the threshold voltage of the selected memory cell MC is lower than the verify level (verify voltage) VL (verify fail), the potential level at the bit line BL is biased to the voltage VSS to perform the additional write in the next period (step or cycle). At this point, the voltage Vpgm of the write pulse PP is stepped up with a constant ratio (step-up voltage ΔVpgm). The threshold voltage of the selected memory cell MC is shifted as illustrated in FIG. 11. When the threshold voltage of the selected memory cell MC is higher than the verify level VL (verify pass), the potential level at the bit line BL connected to the selected memory cell MC is charged to the voltage VDDSA in the next period. Therefore, the additional write is not performed to the selected memory cell MC that passes the verify. Hereinafter, the above-described operation is referred to as “verify write”. When the “verify write” is performed, a distribution width of the threshold voltage distribution of the selected memory cell MC can be narrowed after the write, compared with the case in which the “verify write” is not performed.

When the distribution width of the threshold voltage distribution of the selected memory cell MC is further narrowed after the write, it is necessary to decrease the step-up voltage ΔVpgm of FIG. 10 to increase the number of write steps (write pulses PP). However, the write time for the program operation increases when the number of steps increases.

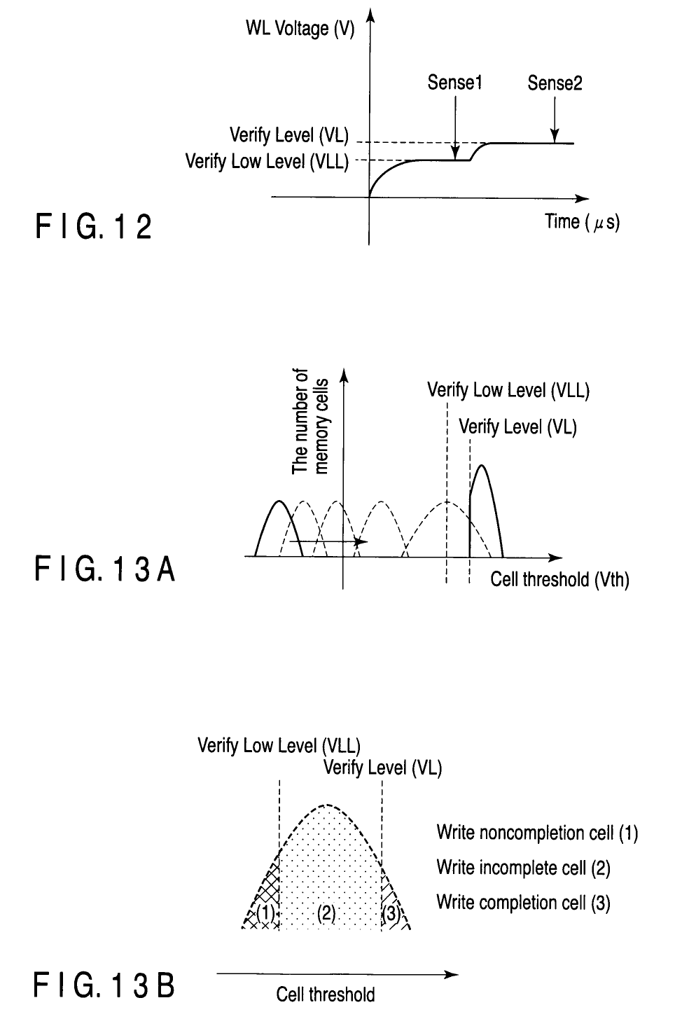

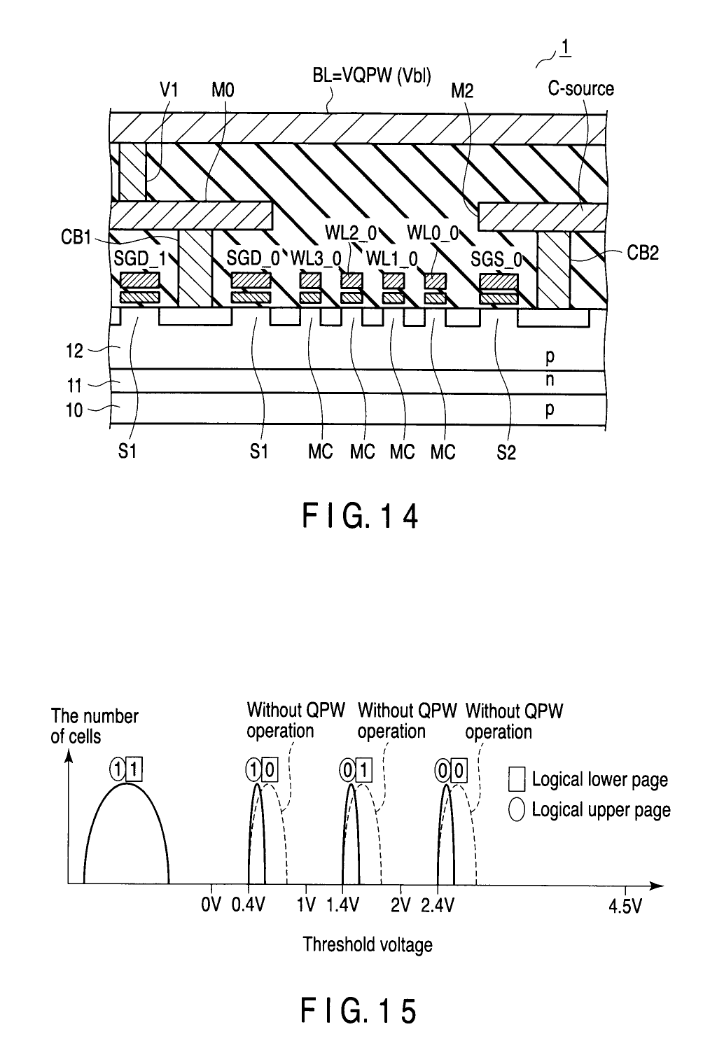

Therefore, there has been proposed the QPW operation in which the distribution width of the threshold voltage can be narrowed after the write while also preventing an increase in the write time. In the QPW operation, for example, as illustrated in FIGS. 12, 13A, and 13B, the sense (Sense 1/Sense 2) is performed at two levels, that is, the verify level VL and the verify low level (Verify low level) VLL, which is lower than the verify level VL during the verify operation. For the selected memory cell (write noncompletion cell (1)) MC whose threshold voltage is lower than the verify low level VLL, the normal write operation (additional write) is performed in the next period. For the selected memory cell (write incomplete cell (2)) MC that passes the verify low level VLL while not passing the verify level VL, for example, as illustrated in FIG. 14, the potential level at the corresponding bit line BL (also referred to as QPW write BL or QPW-BL) is biased to the voltage VQPW (VSS<VQPW<VDDSA) in the next period. Therefore, the channel region is charged by the voltage VQPW, and an electric field that is lower than that of the additional write is applied between the floating gate FG and the channel region, thereby narrowing the threshold voltage distribution width. For the selected memory cell MC that passes the verify level VL, that is, for the write completion cell (3) whose threshold voltage is higher than the verify level VL, the additional write is not performed in the subsequent periods.

In the QPW operation, the step-up voltage ΔVpgm is kept constant, and the threshold voltage distribution width can be narrowed in the memory cell transistor MC after the write while also preventing an increase in the write time.

In performing the QPW operation, the potential level at the bit line BL is controlled by the three voltages, VDDSA, VQPW, and VSS, that are provided by the sense amplifier circuit 201. The sense amplifier circuits 201 substantially simultaneously bias the potential levels at the corresponding bit lines BL to one of the voltage VDDSA, the voltage VQPW, and the voltage VSS before the write operation is started (before the write pulse PP is applied).

Particularly, in the sense amplifier circuit 201 that biases the potential level at the bit line BL to the voltage VQPW, the turn-on timing of the n-channel MOS transistor Qn22 is delayed, for example, by changing gradually the gate voltage of the n-channel MOS transistor Qn22, which avoids the peak current being passed through the bit line BL. Accordingly, even if the page length increases, the time necessary to charge the bit line can be maintained while also preventing the peak current during the charge. In performing the QPW operation, the peak current and the power supply voltage drop can be prevented without lengthening the time required for the write when the bit line level is biased.

An operation of the multi-level flash memory of the first embodiment will briefly be described. In the first embodiment, two-bit data, that is, four-level (four-value) data is stored as multi-level data in one memory cell transistor.

FIG. 15 illustrates a relationship between the two-bit data and the threshold voltage of the memory cell transistor MC in the multi-level flash memory. Two-bit data takes on of four values “11”, “10”, “01”, and “00”. The two bits belong to different row addresses (different pages).

As illustrated in FIG. 15, the two-bit data is stored in the memory cell transistor MC in the form of a difference in threshold voltage. In the first embodiment, it is assumed that “11” data is the state in which the threshold voltage of the memory cell transistor MC becomes the lowest (for example, the threshold voltage is negative), it is assumed that “10” data is the state in which the threshold voltage of the memory cell transistor MC becomes the second lowest (for example, the threshold voltage is positive), it is assumed that “01” data is the state in which the threshold voltage of the memory cell transistor MC becomes the third lowest (for example, the threshold voltage is positive), and it is assumed that “00” data is the state in which the threshold voltage of the memory cell transistor MC becomes the highest (for example, the threshold voltage is positive).

After the data erasing, the data of the memory cell transistor MC becomes the “11” data. When the lower page data written in the memory cell transistor MC is the “0” data, the memory cell transistor MC makes a transition from the state of the “11” data to the state of the “10” data by the write. When the “1” data is written, the memory cell transistor MC remains in the state of the “11” data.

Subsequent to the write of the lower page, the upper page data is written in the memory cell transistor MC. When the write data is the “1” data, the memory cell transistor MC remains in the state of the “11” data or the “10” data. When the write data is the “0” data, the memory cell transistor MC makes the transition from the state of the “11” data to the state of the “01” data by the write, or the memory cell transistor MC makes the transition from the state of the “10” data to the state of the “00” data by the write.

The so-called write verify is performed after the write. In the write verify, the data is read from the memory cell transistor MC, to which the write is performed, to verify whether the write is sufficiently performed. That is, in the data read by the sense amplifier 201, for example, when the threshold voltage is 0V or less, the data is determined to be “11” data. When the threshold voltage ranges from 0V to 1V, the data is determined to be “10” data. When the threshold voltage ranges from 1V to 2V, the data is determined to be “01” data. When the threshold voltage is 2V or more, the data is determined to be “00” data.

The four thresholds are used in the multi-level flash memory in which the two-bit data is stored in one memory cell transistor MC. In an actual device (memory chip), the threshold varies because a variation is generated in a characteristic of the memory cell transistor MC. When the variation increases, the pieces of data cannot be distinguished from one another, which increases the possibility of reading false data.

In the multi-level flash memory of the first embodiment, the large variation of the threshold indicated by a broken line can be suppressed by the QPW operation as indicated by a solid line in FIG. 15. That is, a read margin (threshold voltage difference) can be expanded. Accordingly, the multi-level flash memory of the first embodiment is suitable for not only the storage of two-bit data but also the storage of three-bit data or more.

A gate voltage control circuit of the first embodiment that controls the rising of the SET transistor will be described below.

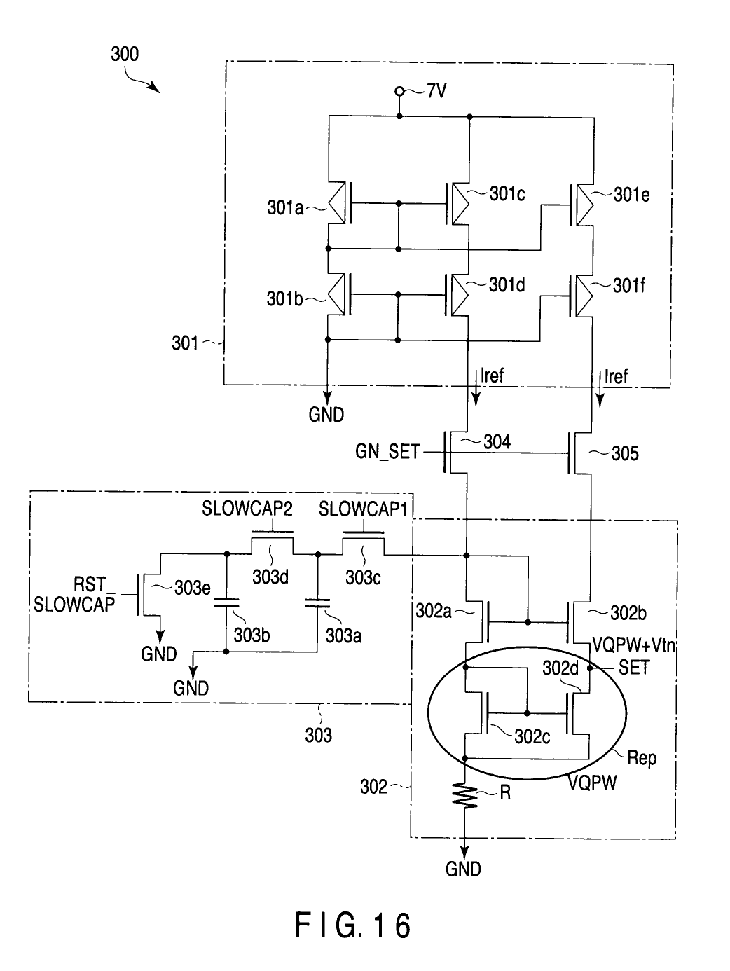

FIG. 16 illustrates a configuration example of a gate voltage control circuit 300 that produces the signal SET, and the signal SET is used to control the gate voltage of the n-channel MOS transistor Qn22 in the sense amplifier circuit 201. The gate voltage control circuit 300 is a power supply circuit that delays the timing of which the n-channel MOS transistor Qn22 turns on when the potential level at the corresponding bit line BL is clamped to the voltage VQPW in the QPW operation. For example, the gate voltage control circuits 300 are provided in the sense amplifiers 14A, 15A, 14B, and 15B (or peripheral circuit 3 and controller 18, or column decoders 20A and 20B).

As illustrated in FIG. 16, the gate voltage control circuit 300 includes a constant current circuit 301, a constant voltage circuit 302, a capacitor circuit (SLOWCAP) 303, and n-channel MOS transistors 304 and 305. The constant current circuit 301 includes p-channel MOS transistors 301a to 301f, and the constant current circuit 301 produces constant current Iref (for example, current value of 10 μA) based on the power supply voltage (for example, 7V). The constant current Iref produced by the constant current circuit 301 is supplied to the constant voltage circuit 302 through the n-channel MOS transistors 304 and 305.

The n-channel MOS transistors 304 and 305 perform on/off control of the gate voltage control circuit 300. For example, the controller 18 provides a high-level signal GN_SET to each gate when the gate voltage control circuit 300 is turned on.

The constant voltage circuit 302 includes n-channel MOS transistors 302a to 302d and a resistive element (for example, resistance value of 60 kΩ) R, and the constant voltage circuit 302 generates the signal SET (for example, gate voltage VQPW+Vtn) that is applied to the gate of the n-channel MOS transistor Qn22 in the corresponding sense amplifier circuit 201. In the n-channel MOS transistors 302c and 302d, a transistor having the same size as the n-channel MOS transistor Qn22 is used to form a replica circuit Rep. That is, the constant voltage circuit 302 produces the voltage VQPW (for example, voltage value of 0.6V) by a product of the resistive element R and the constant current Iref supplied from the constant current circuit 301, and the constant voltage circuit 302 produces the gate voltage VQPW+Vtn using the replica circuit Rep based on the voltage VQPW.

The capacitor circuit 303 includes capacitors 303a and 303b that adjust a rising time of the gate voltage VQPW+Vtn of the constant voltage circuit 302, n-channel MOS transistors 303c and 303d that charge the capacitors 303a and 303b, respectively, and an n-channel MOS transistor 303e that discharges the capacitors 303a and 303b. During the on time, a gate signal SLOWCAP1 of the n-channel MOS transistor 303c, a gate signal SLOWCAP2 of the n-channel MOS transistor 303d are set to a high level, and a gate signal RST_SLOWCAP of the n-channel MOS transistor 303e is set to a low level by the controller 18.

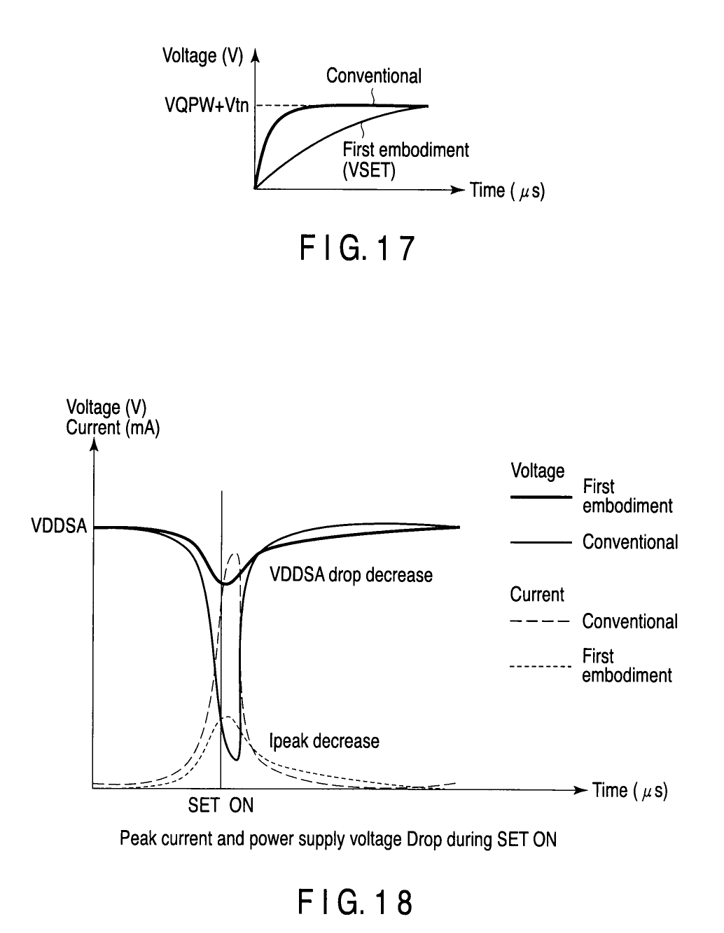

In the gate voltage control circuit 300 of the first embodiment, for example, as illustrated in FIG. 17, the rising speed of the produced gate voltage VQPW+Vtn can be slowed by charging the capacitors 303a and 303b. The rising speed of the gate voltage VQPW+Vtn depends on the capacitance of the connected capacitors 303a and 303b. When the n-channel MOS transistors 303c and 303d are put into the off state while the gate signals SLOWCAP1 and SLOWCAP2 are set to a low level, because the capacitors 303a and 303b are not charged, the gate voltage VQPW+Vtn rises steeply (i.e. rapidly, for example, time required for rising the voltage is 20 ns). When the n-channel MOS transistors 303c and 303d are put into the on state while the gate signals SLOWCAP1 and SLOWCAP2 are set to a high level, the rising of the gate voltage VQPW+Vtn has a certain gradient according to the charge amount of the capacitors 303a and 303b (i.e. slowly, for example, 8 μs). The rising speed can arbitrarily be set by changing the capacitance of the capacitors 303a and 303b.

The change in rising speed is not limited to the case in which the n-channel MOS transistors 303c and 303d are simultaneously put into the on state, and can easily be changed by controlling the connection of the capacitors 303a and 303b.

For example, as illustrated in FIG. 18, when the potential level at the corresponding bit line BL is clamped to the voltage VQPW, the peak current passed through the bit line BL and the drop of the power supply voltage VDDSA can be prevented by delaying the timing if which the n-channel MOS transistor Qn22 turns on using the gate voltage control circuit 300. The timing of which the n-channel MOS transistor Qn22 turns on is set to short sufficiently within the time period in which the non-selected word line WL is charged by the voltage VPASS before the write pulse PP is applied and the time period in which the selected word line WL is charged by the voltage Vpgm (for example, 9 μs). Therefore, any detriment to the performance can be avoided.

An operation example of the sense amplifier circuit 201 of the multi-level flash memory of the first embodiment in the QPW operation during the program operation will specifically be described below.

In the initial setting, in the sense amplifier circuits 201 corresponding to the write cell MC (0-BL), the non-write cells MC (1-BL) including the QPW write cell MC that passes the verify level VL, and the QPW write cell MC (QPW-BL) that passes the verify low level VLL, the signal INV and the signal SEN are set as illustrated in TABLE 1. Therefore, using each of the sense amplifier circuits 201 having the same configuration, through each current pass of FIG. 7, the potential level at the bit line BL can be clamped to the voltage VSS for the write cell MC that is the write noncompletion cell, the potential level at the bit line BL can be clamped to the voltage VDDSA for the non-write cells MC including the QPW write cell MC that is the write completion cell passing the verify level VL, and the potential level at the bit line BL can be clamped to the voltage VQPW for the QPW write cell MC that is the write incomplete cell. For example, when the voltage VQPW is provided to the cell MC, the voltage is transferred to the bit line BL through the current passes of the MOS transistors Qn22, QP23, Qn24, and Qn29. At this point, the MOS transistors Qn23, Qn26, and Qn27 are put into the off state, and the off state is indicated by the sign (x) in FIG. 7. When the voltage VDDSA is provided to the cell MC, the voltage is transferred to the bit line BL through the current passes of the MOS transistors Qn28, Qn25, Qn24, Qp23, and Qn29. When the voltage VSS is provided to the cell MC, the voltage is transferred to the bit line BL through the current passes of the MOS transistors Qn30 and Qn29.

TABLE 1

| | INV | SEN | BL level |
|---|---|---|---|
| 0-BL | VDDSA | VDDSA + VCLK | VSS |
| QPW-BL | VSS | VSS | VQPW |
| 1-BL | VSS | VDDSA + VCLK | VDDSA |

“VCLK” of TABLE 1 expresses the voltage provided as the signal CLK.

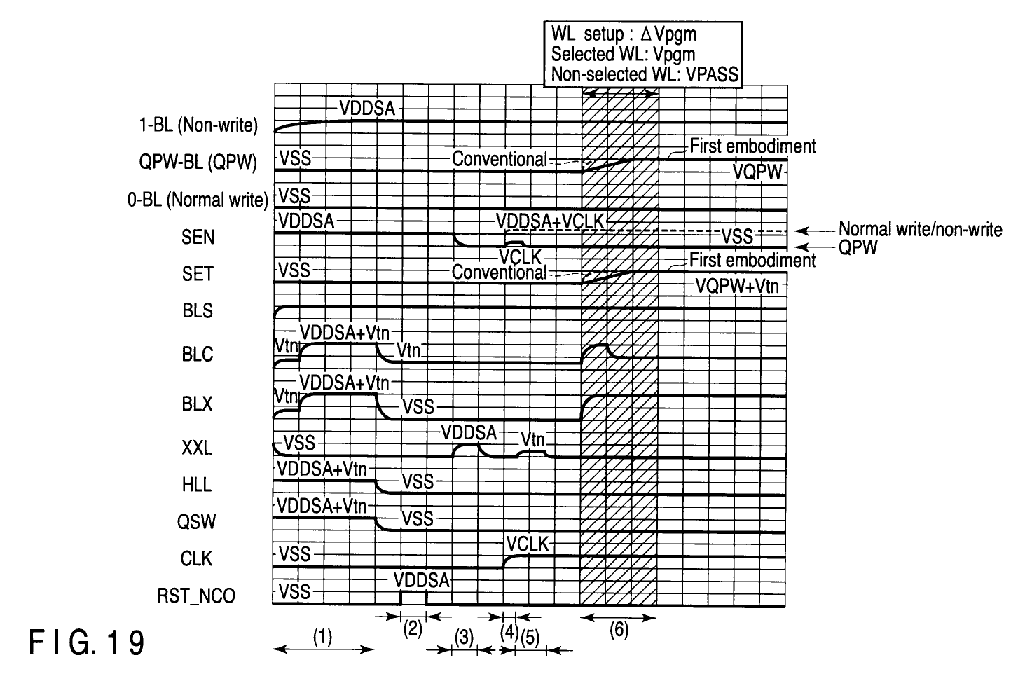

FIG. 19 illustrates a processing flow (program sequence of the sense amplifier circuit 201 of FIG. 7) in the QPW operation as contrasted with a conventional technique.

In the QPW operation, first the pieces of data of the internal latch circuits 201a in all the sense amplifier circuits 201 are reset as the initial setting (INV=“H(VDDSA)”). The signal RST_NCO is set to “H” to turn on the n-channel MOS transistor Qn21. The write data (write data “0” or non-write data “1”) in the data buffer 17 is transferred to the internal latch circuit 201a in the sense amplifier circuit 201 through the data bus 16 (Inhibit scan). Therefore, the signal INV of the sense amplifier circuit 201 corresponding to the write cell MC of the normal write remains at “H”, and the signal INV of the sense amplifier circuit 201 corresponding to the non-write cell MC is inverted to “L(VSS)”. Then, the signals HLL, BLX, BLC, and QSW are set to “H (VDDSA+Vtn)” to turn on the n-channel MOS transistors Qn26, Qn25, Qn29, and Qn27. The signal LAT of the reverse phase is turned to “H” by inverting the signal INV to “L”, and the n-channel MOS transistor Qn24 is turned on while the n-channel MOS transistor Qn30 is turned off. As a result, the capacitor Ca (node SEN) and the bit line 1-BL of the non-write cell MC are charged by the voltage VDDSA (see (1) of FIG. 19).

Then, the signal HLL, BLX and QSW are set to “L(VSS)”, the signal BLC is set to “L(Vtn)”, and the n-channel MOS transistors Qn25, Qn26, Qn27 and Qn29 are turned off to end the charge of the capacitor Ca and the bit line 1-BL of the non-write cell MC (the potential level at the bit line 1-BL is clamped to the voltage VDDSA).

Then, the QPW scan is performed (see (2) of FIG. 19), and the signal INV of the sense amplifier circuit 201 corresponding to the QPW write cell MC that passes the verify low level VLL is inverted from “H” to “L”. Therefore, the signal LAT of the reverse phase becomes “H” by inverting the signal INV to “L”, and the n-channel MOS transistor Qn24 and the p-channel MOS transistor Qp23 are turned on (n-channel MOS transistor Qn30 is turned off).

Then, the signal XXL of the sense amplifier circuit 201 corresponding to the QPW write cell MC is set to “H (VDDSA)” to turn on the n-channel MOS transistor Qn23. Therefore, the potential at the node SEN is discharged from the voltage VDDSA to the voltage VSS in the sense amplifier circuit 201 corresponding to the QPW write cell MC. The potential at the node SEN is retained at the voltage VDDSA in the sense amplifier circuits 201 corresponding to the non-write cell MC and the normal write cell MC that does not pass the verify low level VLL (see (3) of FIG. 19).

Then, the signals XXL of all the sense amplifier circuits 201 are set to “L” to turn off the n-channel MOS transistor Qn23. Then, the voltage VCLK is provided as the signal CLK (CLKup) to boost the potential at the node SEN by the voltage VCLK (see (4) of FIG. 19).

Then, the signals XXL of all the sense amplifier circuits 201 are set to “H (Vtn)” to turn on the n-channel MOS transistor Qn23. Therefore, the potential at the node SEN is discharged from the voltage VCLK to the voltage VSS in the sense amplifier circuit 201 corresponding to the QPW write cell MC (see (5) of FIG. 19).

After the signals XXL of all the sense amplifier circuits 201 are set to “L” to turn off the n-channel MOS transistor Qn23, the signals BLX and BLC are set to “H (VDDSA+Vtn)”, and the signal SET is set to “H (VQPW+Vtn)”. Therefore, for the sense amplifier circuits 201 corresponding to the non-write cell MC including the normal write cell MC that passes the verify level VL, because the signal INV is set to “L(VSS)” while the signal SEN is set to “H (VDDSA+VCLK)”, the n-channel MOS transistors Qn28, Qn25, Qn24, Qn29 and the p-channel MOS transistor Qp23 are turned on, whereby the potential level at the bit line 1-BL connected to the sense amplifier circuits 201 corresponding to the non-write cells MC including the normal write cell MC that passes the verify level VL is clamped to the voltage VDDSA. For the sense amplifier circuit 201 corresponding to the normal write cell MC that does not pass the verify low level VLL, because the signal INV is set to “H (VDD)” while the signal SEN is set to “H (VDDSA+VCLK)”, the n-channel MOS transistor Qn29 is turned on, the n-channel MOS transistor Qn24 is turned off, and the p-channel MOS transistor Qp23 is turned off, whereby the potential level at the bit line 0-BL connected to the sense amplifier circuit 201 corresponding to the normal write cell MC that does not pass the verify low level VLL is clamped to the voltage VSS.

On the other hand, the potential level at the bit line QPW-BL connected to the sense amplifier circuit 201 corresponding to the QPW write cell MC that passes the verify low level VLL is clamped to the voltage VQPW. That is, for the sense amplifier circuit 201 corresponding to the QPW write cell MC, because the signal INV is set to “L (VSS)” while the signal SEN is set to “L (VSS)”, the n-channel MOS transistors Qn29, Qn24, and Qn22 are turned on, the n-channel MOS transistors Qn28 and Qn30 are turned off, and the p-channel MOS transistor Qp23 is turned on, whereby the potential level at the bit line QPW-BL connected to the sense amplifier circuit 201 corresponding to the QPW write cell MC is clamped to the voltage VQPW.

At this point, as illustrated in FIG. 17, the gate voltage control circuit 300 of FIG. 16 controls the gate voltage (VQPW+Vtn) VSET such that the n-channel MOS transistor Qn22 rises slowly. Therefore, for example, as illustrated in FIG. 18, when the n-channel MOS transistor Qn22 is turned on, the peak current passed through the corresponding bit line QPW-BL and the drop of the power supply voltage VDDSA can be prevented.

That is, the gate voltage control circuit 300 performs control such that the rising speed of the signal SET that is provided as the gate voltage VSET to the gate of the n-channel MOS transistor Qn22 is slowed than conventional scheme according to the charge time of the capacitors 303a and 303b in the sense amplifier circuit 201 corresponding to the QPW write cell MC that passes the verify low level VLL. Therefore, because the turning-on timing of the n-channel MOS transistor Qn22 is delayed, the voltage VQPW that is provided as the signal BUS to charge the corresponding bit line QPW-BL can gradually be boosted.

Through the above operation, the non-write bit lines 1-BL including the bit line 0-BL connected to the normal write cell MC, which is the write completion cell whose threshold voltage exceeds the verify level VL to become the verify pass, are maintained at the voltage VDDSA (for example, 2.2V); the normal write bit line 0-BL whose threshold voltage does not exceed the verify low level VLL to become the verify fail is maintained at the voltage VSS (0V); and the normal write bit line QPW-BL whose threshold voltage exceeds the verify low level VLL to become the verify low pass is maintained at the voltage VQPW (for example, 0.6V).

Then, the verify write is performed within 9 μs from the beginning of the QPW operation. The data write is repeatedly performed to the write noncompletion cell and the write incomplete cell by applying the write pulse (program voltage Vpgm+step-up voltage ΔVpgm) PP to the selected word line WL until the data write is completed to all the write cells MC (threshold voltage passes the verify level VL) (see (6) of FIG. 19).

As described above, in performing the QPW operation, when the potential level at the bit line QPW-BL is biased to the voltage VQPW before the write pulse PP is applied, the peak current and the power supply voltage drop can be prevented without delaying the write time. In the configuration of the first embodiment, the turning-on timing of the n-channel MOS transistor Qn22 is delayed so as to be completely turned on in the period during which the word line voltage is set up until the write pulse PP is applied. Therefore, the voltage VQPW that is applied to the QPW write cell MC to charge the bit line QPW-BL can slowly be boosted. Accordingly, even if the page length increases, the peak current and the power supply voltage drop, when the potential level at the corresponding bit line QPW-BL is biased to the voltage VQPW, can be prevented without lengthening the write time period.

Additionally, the multi-level flash memory of the first embodiment can easily be implemented, because only some p-channel MOS transistors and n-channel MOS transistors are added to the existing (conventional) sense amplifier.

In the first embodiment, a multi-level flash memory having a two-plane configuration in which the memory cell array is divided into two in the word line direction is described by way of example. The embodiment is not limited to the present configuration.

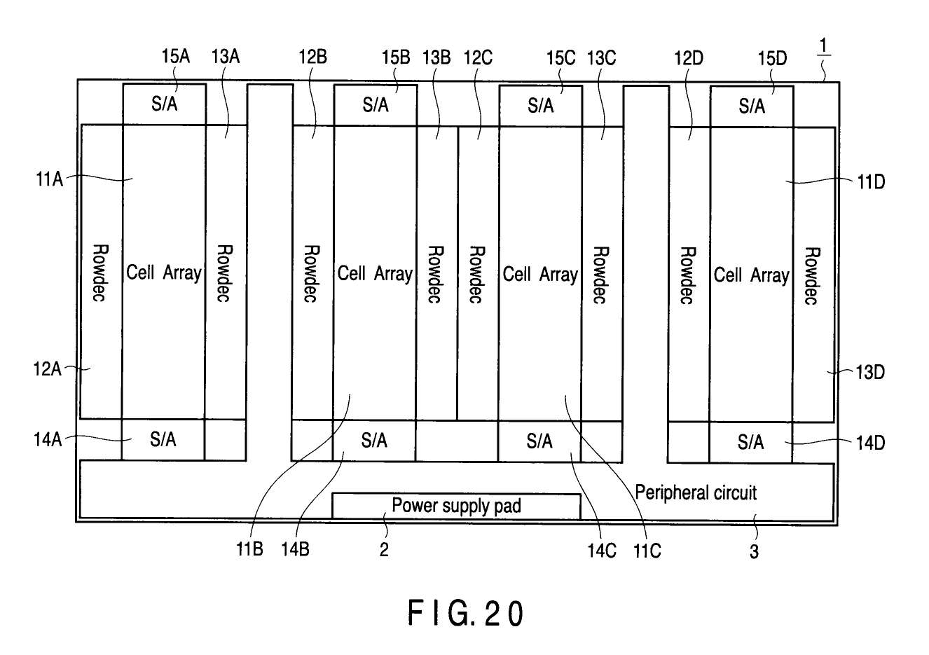

For example, as illustrated in FIG. 20, the present embodiment can also be applied to a multi-level flash memory having a so-called four-plane configuration, in which at least two (in FIG. 20, four) memory cell arrays 11A, 11B, 11C, and 11D are disposed along the word line WL on the chip 1.

### Second Embodiment

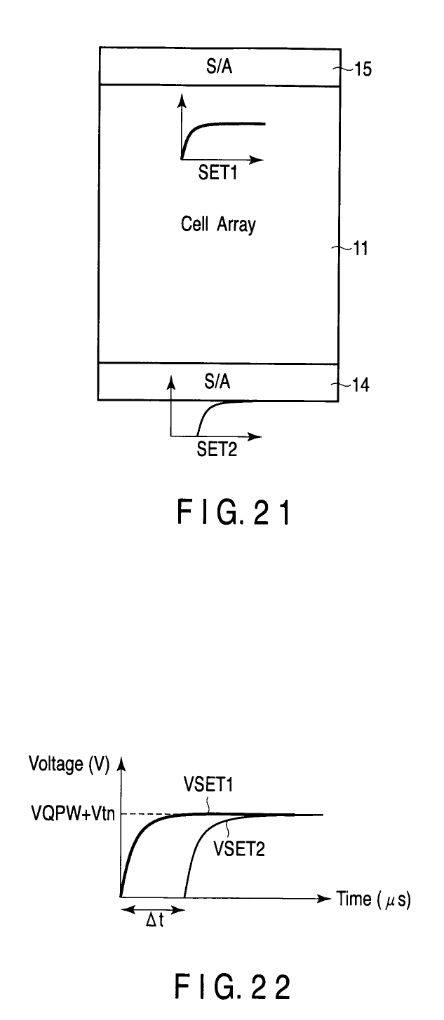

FIG. 21 illustrates an example of a nonvolatile semiconductor storage device according to a second embodiment of the present invention. In FIG. 21, the same components as in the first embodiment are designated by the same numerals, and the detailed description thereof are omitted.

In the multi-level NAND flash memory which has the configuration of plural (or single) planes and which performs the QPW operation, as illustrated in FIG. 21, each of the n-channel MOS transistors (SET transistor) Qn22 of the sense amplifier circuit 201 in the sense amplifiers (S/A) 14 and 15 disposed above and below the memory cell array (Plane) 11 is divided into SET transistors SET1 and SET2. As illustrated in FIG. 22, when the control (in-plane control) is performed such that the SET transistors SET1 and SET2 are turned on while the turn-on times are shifted from each other by Δt (for example, 5 μs), the peak current passed through the bit line QPW-BL and the power supply voltage drop can be prevented in turning on the SET transistors SET1 and SET2, similarly to the first embodiment.

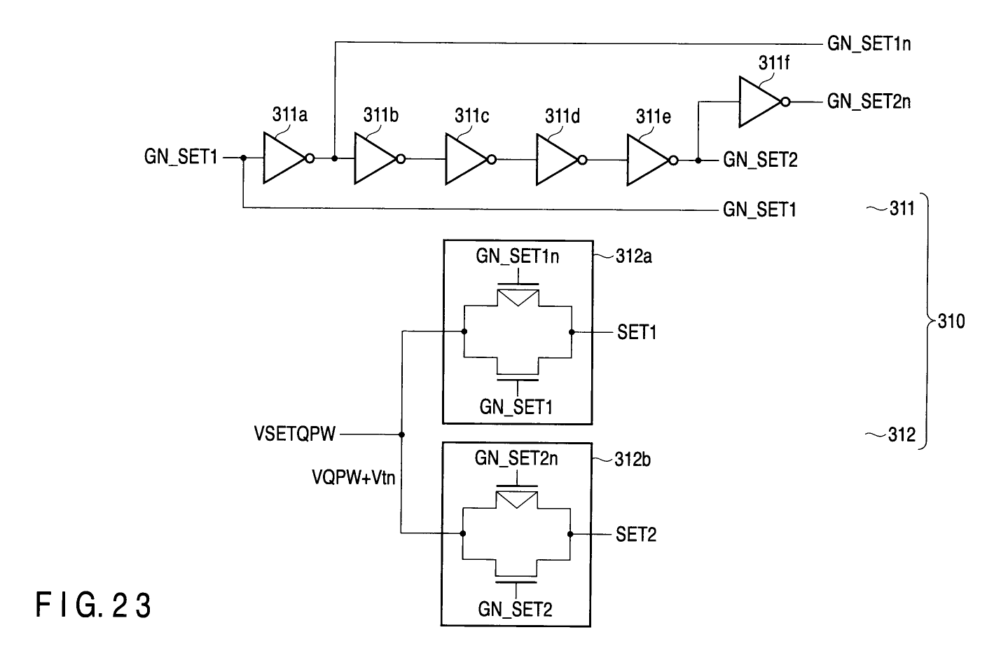

FIG. 23 illustrates a configuration example of the gate voltage control circuit that controls the timing of which the SET transistors SET1 and SET2 turns on. Referring to FIG. 23, a gate voltage control circuit 310 includes a delay circuit 311 and a transfer gate circuit 312.

The delay circuit 311 includes plural delay elements (for example, delay elements 311a to 311e) that are connected in series according to the shift timing between the SET transistors SET1 and SET2 and a delay element 311f that is connected in series to the delay elements 311a to 311e. The delay circuit 311 produces gate control signals GN_SET1, GN_SET1n, GN_SET2, and GN_SET2n. For example, the signal SET is directly taken out as the gate control signal GN_SET1, the output of the delay element 311a is taken out as the gate control signal GN_SET1n that is the inverting signal of the GN_SET1, the output of the delay element 311e is taken out as the gate control signal GN_SET2, and the output of the delay element 311f is taken out as the gate control signal GN_SET2n that is the inverting signal of the GN_SET2.

The transfer gate circuit 312 includes transfer gates 312a and 312b, and each of the transfer gates 312a and 312b includes an n-channel MOS transistor and a p-channel MOS transistor. The transfer gate circuit 312 produces gate voltages VSET1 and VSET2 at the SET transistors SET1 and SET2 according to the gate control signals GN_SET1, GN_SET1n, GN_SET2, and GN_SET2n.

The gate control signal GN_SET1 is provided to the gate of the n-channel MOS transistor of the transfer gate 312a, and the gate control signal GN_SET1n is provided to the gate of the p-channel MOS transistor. The voltage VSETQPW (VQPW+Vtn) is provided as the gate voltage VSET1 to the gate of the SET transistor SET1 at the time the gate control signal GNSET1 is set to “H” (gate control signal GN_SET1n is set to “L”), and the SET transistor SET1 is turned on meanwhile. Similarly, the gate control signal GN_SET2 is provided to the gate of the n-channel MOS transistor of the transfer gate 312b, and the gate control signal GNSET2n is provided to the gate of the p-channel MOS transistor. The voltage VSETQpW (VQPW+Vtn) is provided as the gate voltage VSET2 to the gate of the SET transistor SET2 at the time the gate control signal GNSET2 is set to “H” (gate control signal GN_SET2n is set to “L”), and the SET transistor SET2 is turned on meanwhile.

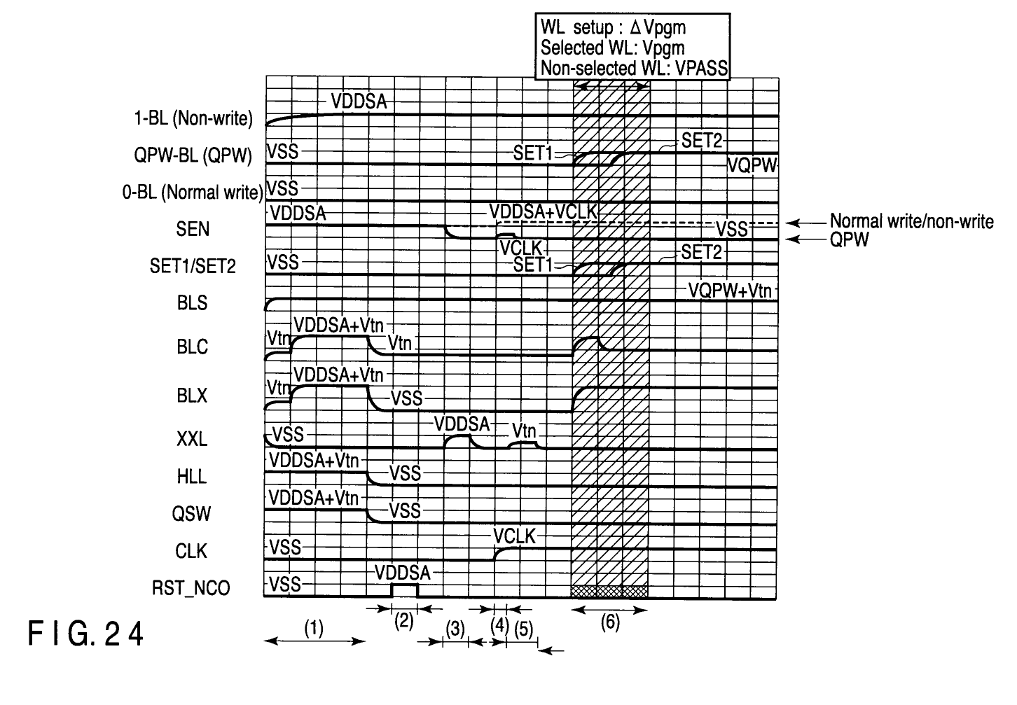

The transfer gates 312a and 312b of the transfer gate circuit 312 are controlled by the gate control signals GN_SET1, GN_SET1n, GN_SET2, and GN_SET2n that are produced by the delay circuit 311, whereby the SET transistors SET1 and SET2 are turned on while shifted from each other by a certain time. That is, the turn-on times can arbitrarily be shifted in the SET transistors SET1 and SET2. As illustrated in FIG. 24, the turn-on times of the SET transistors SET1 and SET2 are shifted in the period during which the word line voltage is set up until the write pulse PP is applied. Therefore, even if the page length increases, the peak current and the power supply voltage drop can be prevented without lengthening the write time period when the potential level at the corresponding bit line QPW-BL is biased to the voltage VQPW.

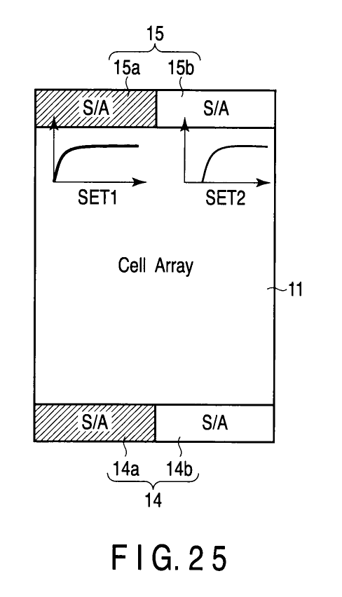

In the second embodiment, the control (in-plane control) is performed such that the turn-on times of the SET transistors SET1 and SET2 are shifted in the S/As 14 and 15 disposed above and below the memory cell array 11. However, the present embodiment is not limited to this configuration. For example, as illustrated in FIG. 25, each of the S/As 14 and 15 disposed above and below the memory cell array 11 are horizontally divided, the control (in-plane control) is performed such that the SET transistor SET1 of the left S/As 14a and 15a and the SET transistor SET2 of the right S/As 14b and 15b are turned on while the turn-on times of the SET transistor SET1 and the SET transistor SET2 are shifted. Therefore, similarly, the peak current passed through the bit line QPW-BL and the power supply voltage drop can be prevented when the SET transistors SET1 and SET2 are turned on.

In each case, the shift time (Δt) the SET transistor SET1 or the SET transistor SET2 is turned on is not limited to 5 μs. The shift time (Δt) is set so as to fall within the set-up time of the word line voltage, whereby the influence on the write time is completely eliminated by setting the shift time to (Δt).

While the turn-on times of the SET transistor SET1 and the SET transistor SET2 are shifted, as with the first embodiment, the control may be performed such that the turn-on time of at least one of the SET transistors SET1 and SET2 is delayed.

### Third Embodiment

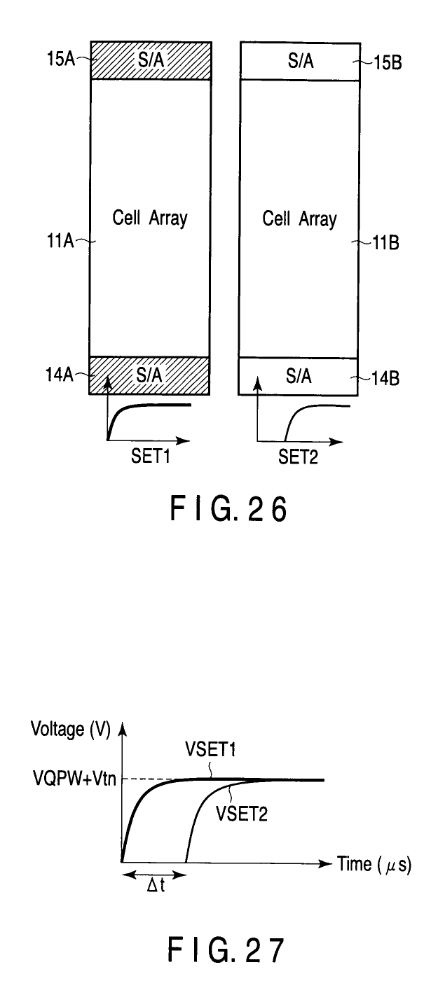

FIG. 26 illustrates an example of a nonvolatile semiconductor storage device according to a third embodiment of the present invention. In FIG. 26, the same components as in the first and second embodiments are designated by the same numerals, and detailed descriptions thereof are omitted.

In the NAND multi-level flash memory which has the configuration of plural planes and which performs the QPW operation, as illustrated in FIG. 26, each of the n-channel MOS transistors (SET transistor) Qn22 of the sense amplifier circuit 201 in the sense amplifiers (S/A) 14A and 14B disposed in the memory cell arrays (Plane) 11A and 11B is divided into SET transistors SET1 and SET2, and each of the n-channel MOS transistors (SET transistor) Qn22 of the sense amplifier circuit 201 in the S/As 14A and 15B disposed in the memory cell arrays 11A and 11B is divided into SET transistors SET1 and SET2. In particularly, SET transistors SET1 are provided in the S/As 14A and 15A, and SET transistors SET2 are provided in the S/As 14B and 15B. As illustrated in FIG. 27, when the control (in-plane unit control) is performed such that the SET transistors SET1 and SET2 are turned on while the turn-on times are shifted from each other by Δt (for example, 5 μs), the peak current passed through the bit line QPW-BL and the power supply voltage drop can be prevented in turning on the SET transistors SET1 and SET2 similarly to the first and second embodiments.

For example, when the SET transistors SET1 and SET2 are controlled by the gate voltage control circuit 310 of FIG. 23, the turn-on times of the SET transistors SET1 and SET2 can be shifted in each memory cell arrays 11A and 11B in the period during which the word line voltage is set up until the write pulse PP is applied (see FIG. 24). Therefore, even if the page length increases, the peak current and the power supply voltage drop can be prevented without lengthening the write time period when the potential level at the corresponding bit line QPW-BL is biased to the voltage VQPW.

In the third embodiment, the shift time (Δt) the SET transistor SET1 or the SET transistor SET2 is turned on is not limited to 5 μs. The shift time (Δt) is set so as to fall within the set-up time of the word line voltage, whereby the influence on the write time is completely eliminated by setting the shift time to (Δt).

### Another Embodiment

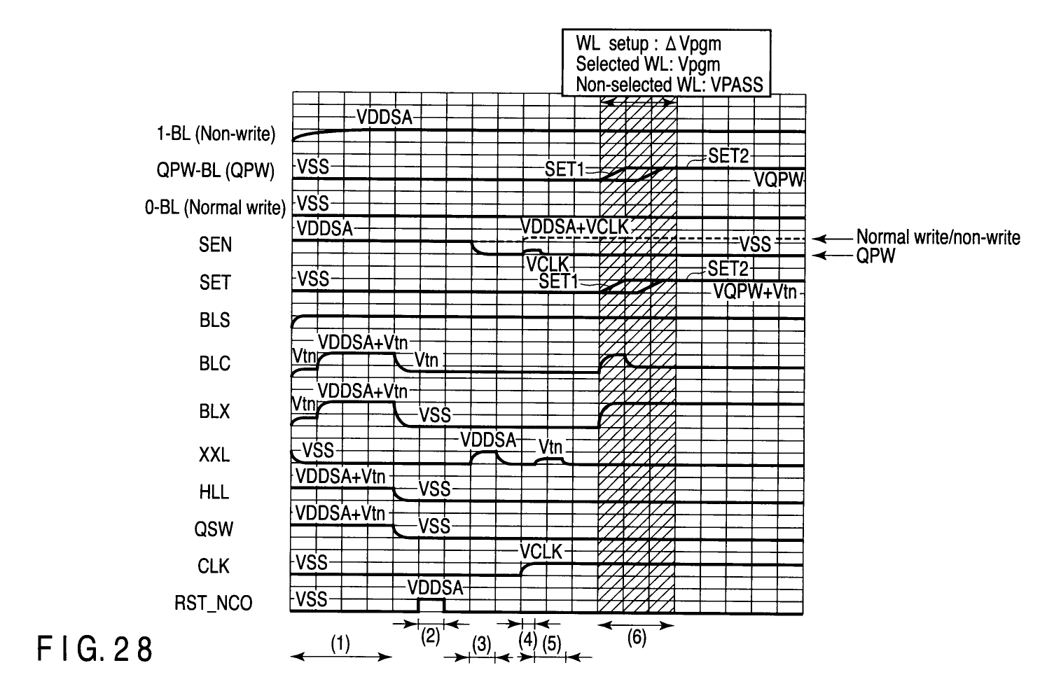

As illustrated in FIG. 28, while the turn-on times of the SET transistor SET1 and the SET transistor SET2 are shifted (for example, 2 μs), as with the first embodiment, the control may be performed such that the turn-on speed of at least one of the SET transistors SET1 and SET2 is slowed (for example, 3 μs).

As described above, the semiconductor memory device according to the first to third embodiments of the present invention includes the nonvolatile memory cell MC, the bit line BL, the first control circuit (the row decoders 12A, 12B, 13A, and 13B and the sense amplifiers 11A, 11B, 14A, and 14B, hereinafter referred to as first control circuits 11 to 14), and the second control circuit (gate voltage control circuit 300). The first control circuits 11 to 14 supply the write voltage Vpgm and the write control voltage VSS to the selected memory cell MC to write the data in the selected memory cell MC, the first control circuits 11 to 14 further write the data by changing the supply state VSS of the write control voltage (from VSS to VQPW) when the selected memory cell MC reaches a first write state (verify low level VLL) by the write, and the first control circuits 11 to 14 prohibit the write by further changing the supply state VQPW of the write control voltage (from VQPW to VDDSA) when the selected memory cell MC reaches a second write state (verify level VL). The second control circuit 300 controls the rising of the write control voltage VQPW when the first control circuits 11 to 14 starts the writing to make the selected memory cell the second write state.

For example, the second control circuit 300 performs control such that the rising speed of the write control voltage VQPW is slowed. In particularly, the rising speed of the write control voltage VQPW is slowed than the rising speed of the write control voltage VDDSA for write-prohibition. Alternatively, the second control circuit 300 performs control such that the rising timing of the write control voltage VQPW is delayed.

Additional advantages and modifications will readily occur to those skilled in the art. Therefore, the present invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor memory device comprising:
a plurality of nonvolatile memory cells in which pieces of data are stored as thresholds having different levels;
a plurality of bit lines which are connected to the nonvolatile memory cells;
a first control circuit which supplies a write voltage and a write control voltage to a selected memory cell to write the data in the selected memory cell, the first control circuit changing a supply state of the write control voltage to further write the data when the selected memory cell reaches a first write state by the write, the first control circuit further changing the supply state of the write control voltage to prohibit the write when the selected memory cell reaches a second write state by the write; and
a second control circuit which controls a rising of the write control voltage when the first control circuit starts the writing to make the selected memory cell the second write state.

2. The device according to claim 1, wherein the second control circuit slows a rising speed of the write control voltage.

3. The device according to claim 1, wherein the second control circuit delays a rising timing of the write control voltage.

4. The device according to claim 1, wherein the first control circuit includes a MOS transistor which is capable of transferring the write control voltage to the bit line in order to put the selected memory cell into the second write state, and
the second control circuit controls a gate potential of the MOS transistor.

5. The device according to claim 4, wherein the second control circuit includes a capacitor element, and
the second control circuit controls a rate of change of the gate potential of the MOS transistor according to a capacitance of the capacitor element.

6. The device according to claim 5, wherein the capacitance of the capacitor element is variable.

7. The device according to claim 1, wherein the plurality of the bit lines includes a first bit line and a second bit line,
the first control circuit includes first and second MOS transistors which are capable of transferring the write control voltage to first and second bit lines in order to put the selected memory cells into the second write state, respectively, and
the second control circuit controls gate potentials of the first and second MOS transistors.

8. The device according to claim 7, wherein the second control circuit turns on the first MOS transistor before the second MOS transistor is turned on.

9. The device according to claim 8, wherein the second control circuit includes:
first and second transfer gates which transfer gate potentials to the first and second MOS transistors, respectively; and
a delay circuit which delays a first signal to generate a second signal, the first signal turning on the first transfer gate, the second signal turning on the second transfer gate.

10. The device according to claim 1, wherein each of the memory cells is a MOS transistor with a stacked gate, the stacked gate including a charge accumulation layer and a control gate.

11. A method for writing data of a semiconductor memory device, comprising:
supplying a write voltage and a write control voltage to a memory cell to perform first write of data to the memory cell;
changing a supply state of the write control voltage to perform second write when the memory cell reaches a first write state by the first write; and
changing further the supply state of the write control voltage to prohibit the write when the memory cell reaches a second write state by the second write,
wherein a rising speed of the write control voltage is slowed.

12. The method according to claim 11, wherein the device includes:
a MOS transistor which is capable of transferring the write control voltage to a bit line in order to put the memory cell into the second write state; and
a control circuit which includes a capacitor element, the control circuit controlling a rate of change of a gate potential of the MOS transistor according to capacitance of the capacitor element.

13. The method according to claim 2, wherein the capacitance of the capacitor element is variable.

14. The method according to claim 11, wherein the memory cell is a MOS transistor with a stacked gate, the stacked gate including a charge accumulation layer and a control gate.

15. A method for writing data of a semiconductor memory device, comprising:
supplying a write voltage and a write control voltage to a memory cell to perform first write of data to the memory cell;
changing a supply state of the write control voltage to perform second write when the memory cell reaches a first write state by the first write; and
changing further the supply state of the write control voltage to prohibit the write when the memory cell reaches a second write state by the second write,
wherein a rising timing of the write control voltage is delayed in the second write.

16. The method according to claim 15, wherein the write control voltage is provided to a first bit line and a second bit line electrically connected to a current pass of the memory cell, and
the device includes:
first and second MOS transistors which are capable of transferring the write control voltage to first and second bit lines, respectively; and
a control circuit which controls gate potentials of the first and second MOS transistors in the second write.

17. The method according to claim 16, wherein the control circuit turns on the first MOS transistor before the second MOS transistor is turned on in the second write.

18. The method according to claim 15, wherein the memory cell is a MOS transistor with a stacked gate, the stacked gate including a charge accumulation layer and a control gate.
